(19) United States
(12) Patent Application Publication
(10) Pub. No.: US 2011/0070671 A1
(43) Pub. Date: Mar. 24, 2011

(54) FABRICATING METHOD OF A PIXEL UNIT

(75) Inventors: Chin-Yueh Liao, Taipei City (TW); Chih-Chun Yang, Hsinchu County (TW); Chih-Hung Shih, Yilan County (TW); Shine-Kai Tseng, Taoyuan County (TW)

(73) Assignee: AU OPTRONICS CORPORATION, Hsinchu (TW)

(21) Appl. No.: 12/953,472

(22) Filed: Nov. 24, 2010

Related U.S. Application Data
(62) Division of application No. 12/482,433, filed on Jun. 10, 2009.

(30) Foreign Application Priority Data
Apr. 10, 2009 (TW) 98112013

(51) Int. Cl. H01L 33/36

(52) U.S. Cl. 438/23; 257/E33.053

(57) ABSTRACT

A method for fabricating a pixel unit is provided. A TFT is formed on a substrate. A protection layer and a patterned photoresist layer are sequentially formed on the substrate entirely. A patterned protection layer is formed by using the patterned photoresist layer as a mask and partially removing the protection layer, wherein the patterned protection layer has an undercut located at a sidewall thereof. A pixel electrode material layer is formed to cover the substrate, the TFT and the patterned photoresist layer, wherein the electrode material layer is disconnected at the undercut and exposes the undercut. A pixel electrode electrically connected to the TFT is formed by lifting off the patterned photoresist layer and parts of the electrode material layer covering the patterned photoresist layer simultaneously through a stripper, wherein the stripper permeates from the undercut to an interface of the patterned photoresist layer and the patterned protection layer.

### CROSS-REFERENCE TO RELATED APPLICATION

This application is a divisional application of an application Ser. No. 12/482,433, filed on Jun. 10, 2009, now pending, which claims the priority benefit of Taiwan application serial no. 98112013, filed on Apr. 10, 2009. The entirety of each of the above-mentioned patent applications is hereby incorporated by reference herein and made a part of specification.

### BACKGROUND OF THE INVENTION

1. Field of the Invention

The present invention relates to a fabricating method of a pixel structure, and particularly to a fabricating method of a pixel structure having an undercut at a sidewall of a patterned protection layer.

2. Description of Related Art

Generally, pixel structures of a liquid crystal display panel are fabricated by five photolithography and etch processes (5 PEPs). A first patterned metal layer including scan lines and gates of thin film transistors is formed by the first PEP. Channel layers of thin film transistors are formed by the second PEP. A second patterned metal layer including data lines, source and drain of each thin film transistor is formed by the third PEP. A patterned dielectric layer having a plurality of contacts is formed by the fourth PEP. A transparent conductive layer is patterned to form pixel electrodes by the fifth PEP.

In order to enhance throughput and reduce fabrication cost, fabricating methods including less PEPs are adopted by many manufacturers. When the number of PEPs decreases, the fabrication cost is further reduced.

FIG. 1A to FIG. 1E are schematic cross-sectional views illustrating a prior art fabricating method of a pixel unit. Referring to FIG. 1A, a plurality of scan lines (not shown), a plurality of gates 122 electrically connected to the scan lines, and a plurality of capacitor electrodes 122a are formed on the substrate 110 by the first PEP.

Referring to FIG. 1B, a plurality of thin films including a gate insulating material layer, a semiconductor material layer, an ohmic contact material layer, and a metal layer are sequentially formed on the substrate to cover the gates 122. Then, parts of the thin films are etched by the second PEP such that a plurality of thin film transistors 120, storage capacitors 120a, a gate insulator 124, a patterned semiconductor layer 126, a patterned ohmic contact layer 126a, and a patterned metal layer 128 are formed on the substrate 110. In each thin film transistors 120, the patterned metal layer 128 serves as a source 128a and a drain 128b. In the storage capacitor 120a, the patterned metal layer 128 serves as a second capacitor electrode 128c.

Referring to FIG. 1C to FIG. 1E, pixel electrodes electrically connected between the thin film transistors 120 and the storage capacitors 120a are formed on the substrate 110 by the third PEP. Specifically, a protection material layer (not shown) and a patterned photoresist layer 140 are formed on the substrate 110 after the thin film transistors 120 and the storage capacitors 120a are fabricated. Then, the protection material layer is removed by using the patterned photoresist layer 140 as a mask to form a patterned protection layer 130, as shown in FIG. 1C. As shown in FIG. 1C, the drains 128b of the thin film transistor 120 and the storage capacitors 120a are exposed by the patterned protection layer 130.

An electrode material layer 150 is entirely formed over the substrate 110 such that the electrode material layer 150 is electrically connected to the drains 128b of the thin film transistor 120 and the storage capacitors 120a naturally, as shown in FIG. 1D. Afterward, the patterned photoresist layer 140 is removed by stripper such that parts of the electrode material layer 150 located on the patterned photoresist layer 140 is lifted off and a plurality of pixel electrodes 150a are formed accordingly, as shown in FIG. 1E. It is noted that the pixel electrodes 150a are electrically connected to the drains 128b of the thin film transistor 120 and the storage capacitors 120a after parts of the electrode material layer 150 located on the patterned photoresist layer 140 is lifted off.

However, it is difficult to remove the patterned photoresist layer 140 by stripper. Specifically, since the patterned photoresist layer 140 and the patterned protection layer 130 are entirely covered by the electrode material layer 150, stripper used for removing patterned photoresist layer 140 can merely permeates from pin holes of the electrode material layer 150 to the interface of the patterned photoresist layer 140 and the patterned protection layer 130. Therefore, removal of the patterned photoresist layer 140 is difficult or requires lots of time. Since the removal of the patterned photoresist layer 140 is difficult or requires lots of time, the fabricating method of the pixel unit illustrated in FIG. 1A to FIG. 1E is impractical. How to remove the patterned photoresist layer 140 easily and rapidly and how to reduce number of the PEPs are imperative issues to be dealt with.

### SUMMARY OF THE INVENTION

The present invention is directed to a pixel unit having an undercut at a sidewall of a patterned protection.

The present invention is directed to a fabricating method of a pixel unit, wherein a stripper permeates from an undercut easily so as to remove a photoresist.

A method for fabricating a pixel unit is provided. A thin film transistor is formed on a substrate. A protection layer is entirely formed on the substrate to cover the thin film transistor, wherein the protection layer includes a plurality of thin films, the thin films are stacked, and etching rate of at least one of the thin films is higher than that of the other thin films. A patterned photoresist layer is formed on the protection layer. A patterned protection layer is formed by using the patterned photoresist layer as a mask and partially removing the protection layer uncovered by the photoresist, wherein the patterned protection layer has an undercut located at a sidewall thereof. A pixel electrode material layer is formed to cover the substrate, the thin film transistor and the patterned photoresist layer, wherein the electrode material layer is disconnected at the undercut and exposes the undercut. A pixel electrode electrically connected to the thin film transistor is formed by lifting off the patterned photoresist layer and parts of the electrode material layer covering the patterned photoresist layer simultaneously through a stripper, wherein the stripper permeates from the undercut to an interface of the patterned photoresist layer and the patterned protection layer.

In an embodiment of the present invention, the method of fabricating the pixel unit further includes forming a storage capacitor on the substrate.

In an embodiment of the present invention, a method of forming the thin film transistor includes following steps. First, a gate is formed on a substrate. Then, a gate insulating layer is formed on the substrate to cover the gate. Thereafter, a semiconductor layer is formed on the gate insulating layer, wherein the semiconductor layer is located above the gate. Ultimately, a source and a drain are formed on the semiconductor layer, wherein a portion of the drain is exposed by the patterned protection layer.

In an embodiment of the present invention, the method of fabricating the pixel unit further includes forming a storage capacitor on the substrate. The method of fabricating the storage capacitor includes following steps. First, a first capacitor electrode is formed on the substrate, wherein the first capacitor electrode is covered by the gate insulating layer. Then, a second capacitor electrode is formed on the gate insulating layer.

In an embodiment of the present invention, the first capacitor electrode and the gate are formed simultaneously, while the second capacitor electrode, the source and the drain are formed simultaneously.

In an embodiment of the present invention, the pixel electrode is connected to the drain and the second capacitor electrode directly.

In an embodiment of the present invention, a method of forming the protection layer includes the following steps. First, a first thin film is entirely formed on the substrate to cover the thin film transistor. Then, a second thin film is entirely formed on the first thin film, wherein etching rates of the first thin film and the second thin film are different.

In an embodiment of the invention, etching rate of the first thin film is greater than that of the second thin film.

In an embodiment of the invention, the first thin film is a porous thin film and the second thin film is a non-porous thin film.

In an embodiment of the invention, when a mixture of sulfur hexafluoride (SF₆), oxygen and nitrogen are used as a gaseous etchant, etching rate of the porous thin film is between 301 angstroms per second to 600 angstroms per second, and etching rate of the non-porous thin film is between 1 angstrom per second to 300 angstroms per second.

In an embodiment of the invention, etching rate of the first thin film is smaller than that of the second thin film.

In an embodiment of the invention, the first thin film is a non-porous thin film and the second thin film is a porous thin film.

In an embodiment of the present invention, the method of fabricating the pixel unit further includes forming a third thin film on the second thin film entirely.

In an embodiment of the present invention, the patterned protection layer further includes a third thin film disposed on the second thin film.

By adjusting materials and/or number of thin films of the protection layer, an undercut is formed at the sidewall of the patterned protection layer. The undercut allows stripper for removing the patterned photoresist layer permeating to the interface of the patterned photoresist layer and the patterned protection layer such that the difficulty and inconvenience of removal of the patterned photoresist layer can be resolved.

In order to make the aforementioned and other features and advantages of the present invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1E are schematic cross-sectional views illustrating a prior art fabricating method of a pixel unit.

FIG. 2A to FIG. 2E are cross-sectional views illustrating a fabricating method of a pixel unit according to the first embodiment of the present invention.

FIG. 2F to FIG. 2J are cross-sectional views illustrating another fabricating method of a pixel unit according to the first embodiment of the present invention.

FIG. 3A to FIG. 3C are partial enlarged views of the structure within the smaller circle shown in FIG. 2B to FIG. 2D respectively.

FIG. 4A and FIG. 4B are schematic cross-sectional views illustrating an undercut according to the second embodiment of the present invention.

FIG. 5A and FIG. 5B are schematic cross-sectional views illustrating an undercut according to the third embodiment of the present invention.

FIG. 6A and FIG. 6B are schematic cross-sectional views illustrating an undercut according to the fourth embodiment of the present invention.

FIG. 7A and FIG. 7B are schematic cross-sectional views illustrating an undercut according to the fifth embodiment of the present invention.

FIG. 8A and FIG. 8B are schematic cross-sectional views illustrating an undercut according to the sixth embodiment of the present invention.

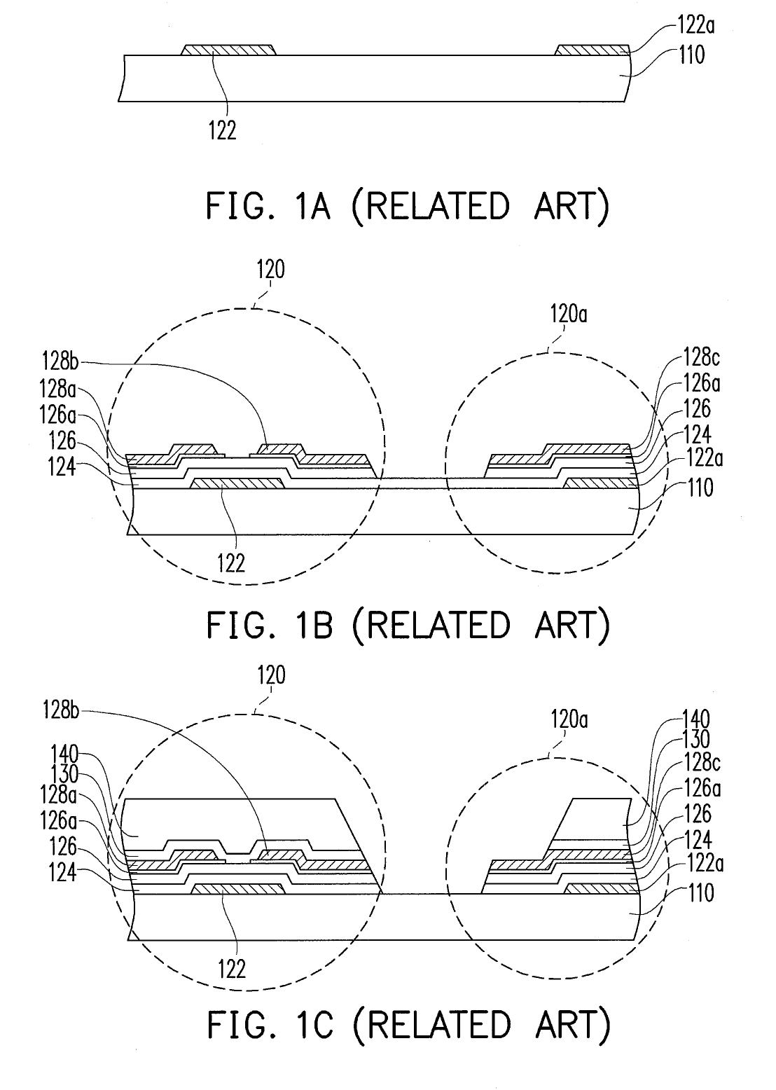

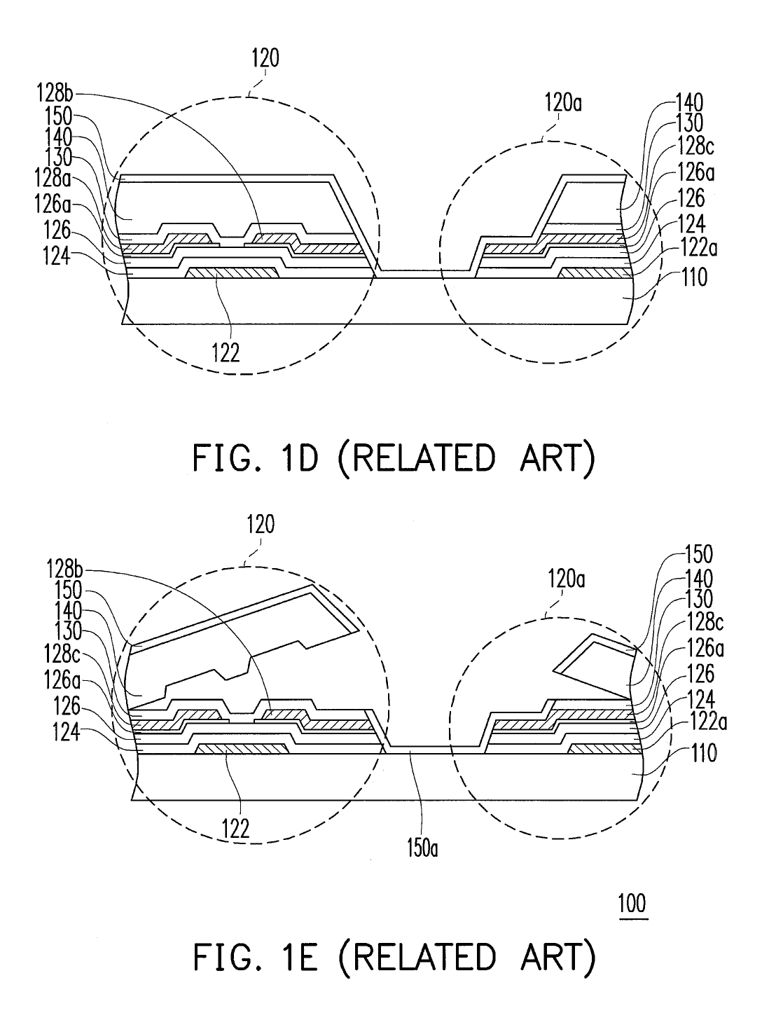

### DESCRIPTION OF EMBODIMENTS

### The First Embodiment

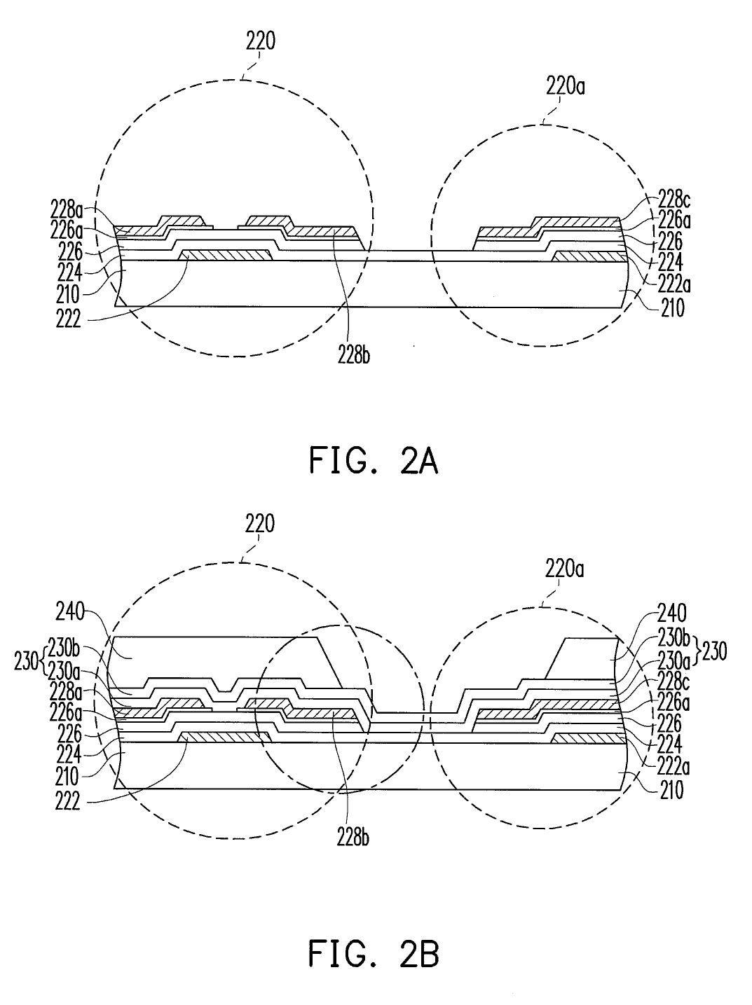

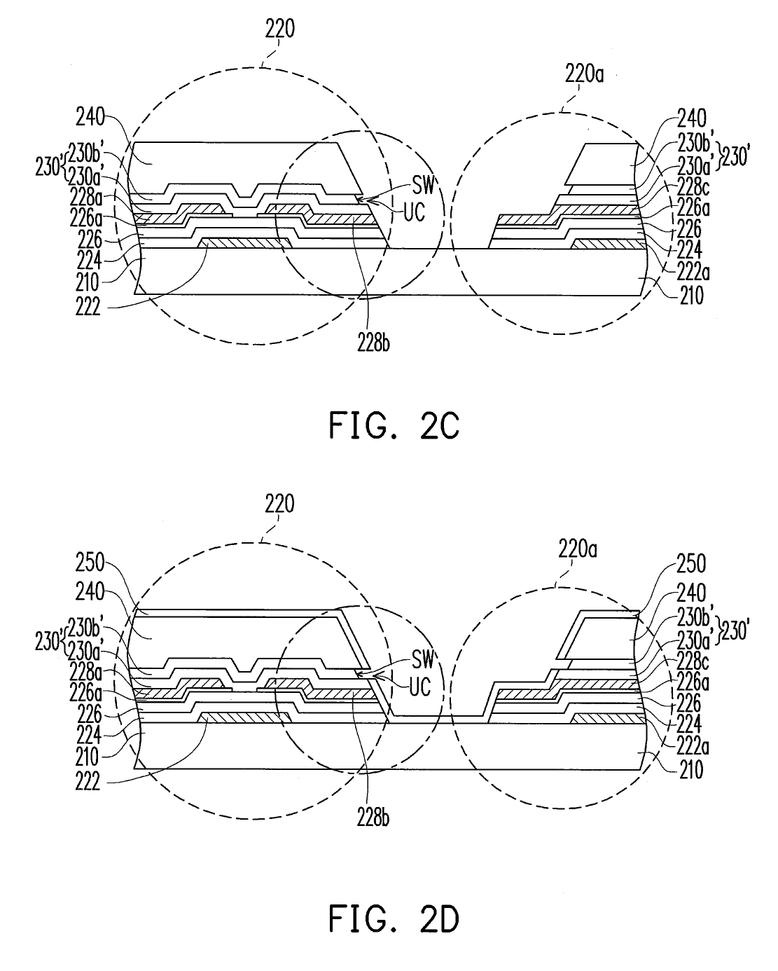

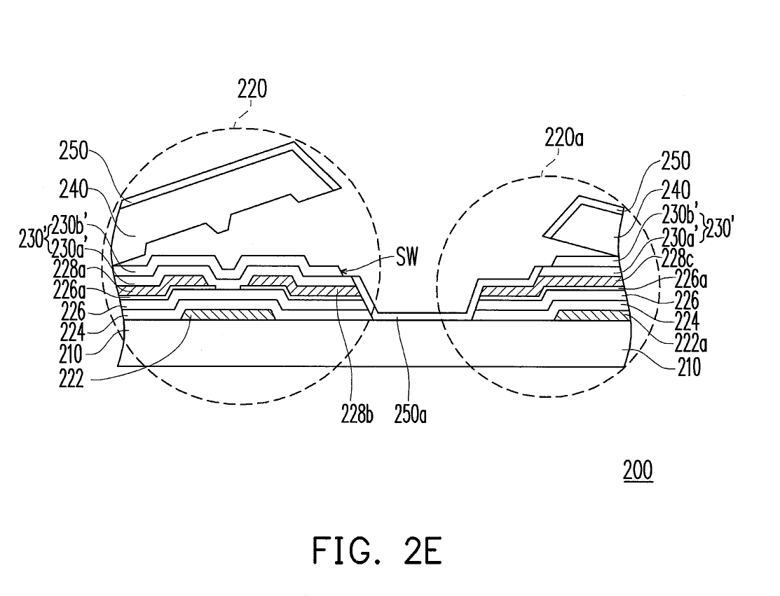

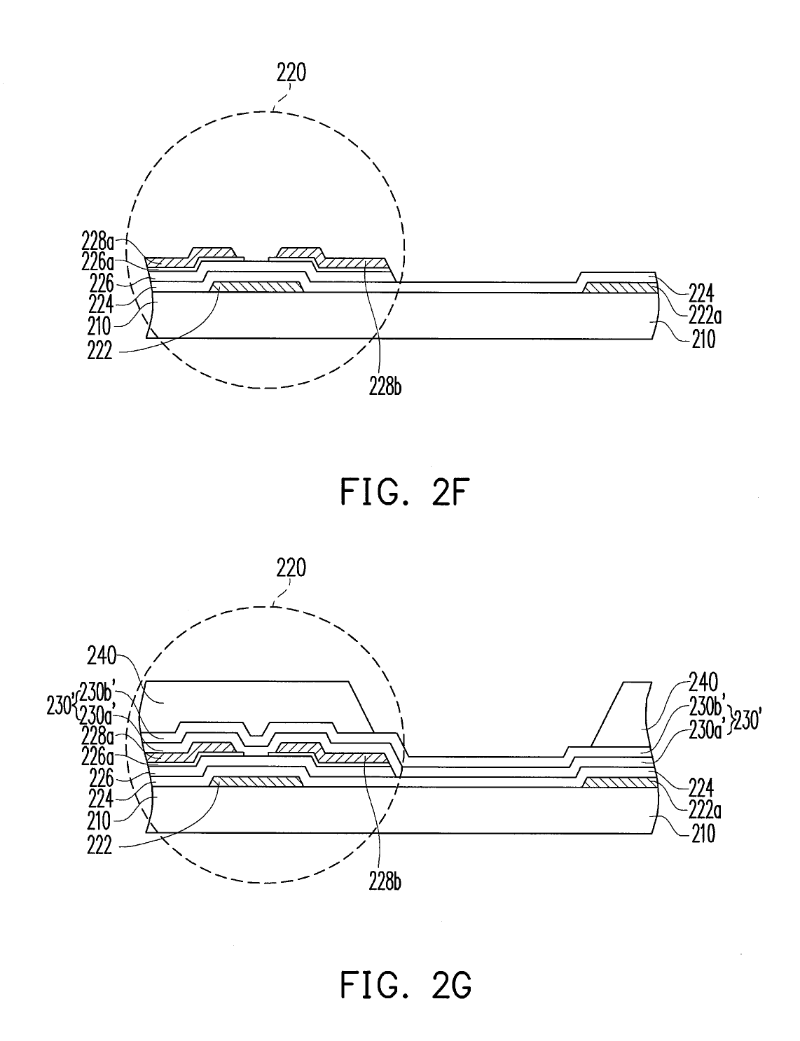

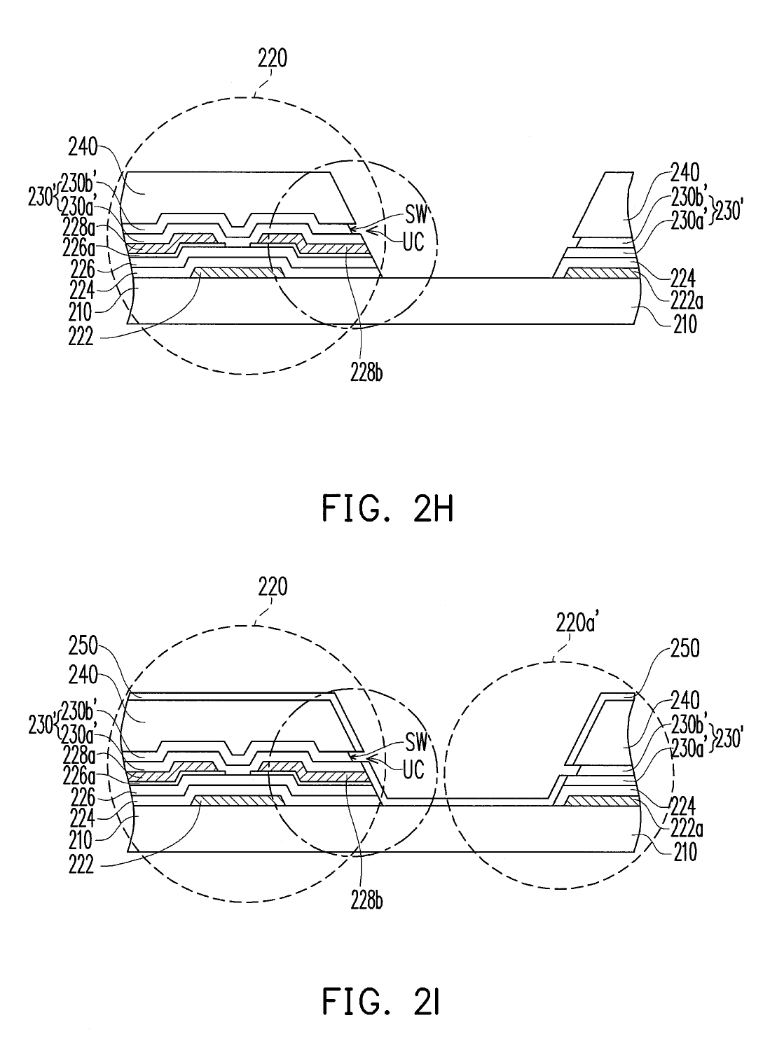

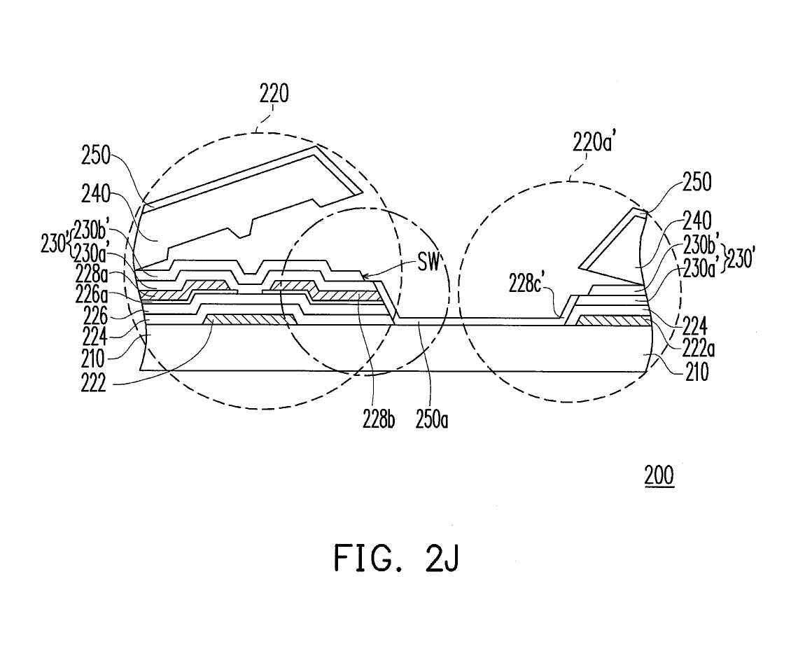

FIG. 2A to FIG. 2E are cross-sectional views illustrating a fabricating method of a pixel unit according to the first embodiment of the present invention. For simplicity, only a portion region of the pixel unit is shown in FIG. 2A to FIG. 2E for illustration.

Referring to FIG. 2A, a thin film transistor (TFT) 220 is formed on the substrate 210 first. In the present embodiment, the material of the substrate 210 includes inorganic transparent materials (i.e. glass, quartz, other suitable materials, or a combination thereof), organic transparent materials (i.e. polyalkene, polyalcohol, polyester, rubber, thermoplastic polymer, thermosetting polymer, polyaromatic, polymethylmethacrylate, polycarbonate, other suitable materials, derivatives thereof, or a combination thereof), inorganic opaque materials (i.e. silica sheet, ceramic, other suitable materials, or a combination thereof), or a combination thereof.

In this embodiment, the method of forming the thin film transistor 220 includes the following steps. First, a gate 222 is formed on the substrate 210. Next, a gate insulating layer 224 is formed on the substrate 210 to cover the gate 222. For instance, the material of the gate insulating layer 224 is inorganic materials such as silicon oxide or silicon nitride. Thereafter, a semiconductor layer 226 is formed on the gate insulating layer 224, and the semiconductor layer 226 is located above the gate 222. Ultimately, a source 228a and a drain 228b are formed over the semiconductor layer 226. Specifically, a heavily doped semiconductor layer 226a may be formed between the semiconductor layer 226 and the source 228a to serve as an ohmic contact layer. In addition, the heavily doped semiconductor layer 226a may be formed between the semiconductor layer 226 and the drain 228b to serve as an ohmic contact layer.

In this embodiment, the method of fabricating the pixel unit further includes forming a storage capacitor 220a on the substrate 210 when forming the thin film transistor 220. The method of fabricating the storage capacitor 220a includes the following steps. First, a first capacitor electrode 222a is formed on the substrate 210, wherein the first capacitor electrode 222a is covered by the gate insulating layer 224. Then, a second capacitor electrode 228c is formed on the gate insulating layer 224. It is noted that the first capacitor electrode 222a and the gate 222 are formed simultaneously, while the second capacitor electrode 228c, the source 228a, and the drain 228b are formed simultaneously. In addition, the semiconductor layer 226 and the heavily doped semiconductor layer 226a may be disposed between the first capacitor electrode 222a and the second capacitor electrode 228c.

Referring to FIG. 2B, a protection layer 230 is formed on the substrate 210 entirely to cover the thin film transistor 220 and the storage capacitor 220a. The protection layer 230 includes a plurality of thin films, the thin films are stacked, and etching rate of at least one of the thin films is higher than that of the other thin films. In this embodiment, the method of forming the protection layer 230 includes the following steps. First, a first thin film 230a is entirely formed on the substrate 210 to cover the thin film transistor 220 and the storage capacitor 220a. Then, a second thin film 230b is entirely formed on the first thin film 230a, wherein etching rate R1 of the first thin film 230a and etching rate R2 of the second thin film 230b are different. For instance, etching rate R1 of the first thin film 230a is smaller than etching rate R2 of the second thin film 230b. In this embodiment, the first thin film 230a is a non-porous thin film and the second thin film 230b is a porous thin film, for example. In this embodiment, density of the above-mentioned porous thin film is between 0.01 g/cm³ to 1.49 g/cm³.

Then, a patterned photoresist layer 240 is formed on the protection layer 230. A portion of the protection layer uncovered by the patterned photoresist layer is removed by using the patterned photoresist layer as a mask such that a patterned protection layer 230′ is formed, as shown in FIG. 2C. In this embodiment, when a mixture of sulfur hexafluoride (SF₆), oxygen and nitrogen are used as gaseous etchant to etch the protection layer 230 uncovered by the patterned photoresist layer 240, etching rate R2 of the second thin film 230b is between 301 angstroms per second to 600 angstroms per second, and etching rate R1 of the first thin film 230a is between 1 angstrom per second to 300 angstroms per second.

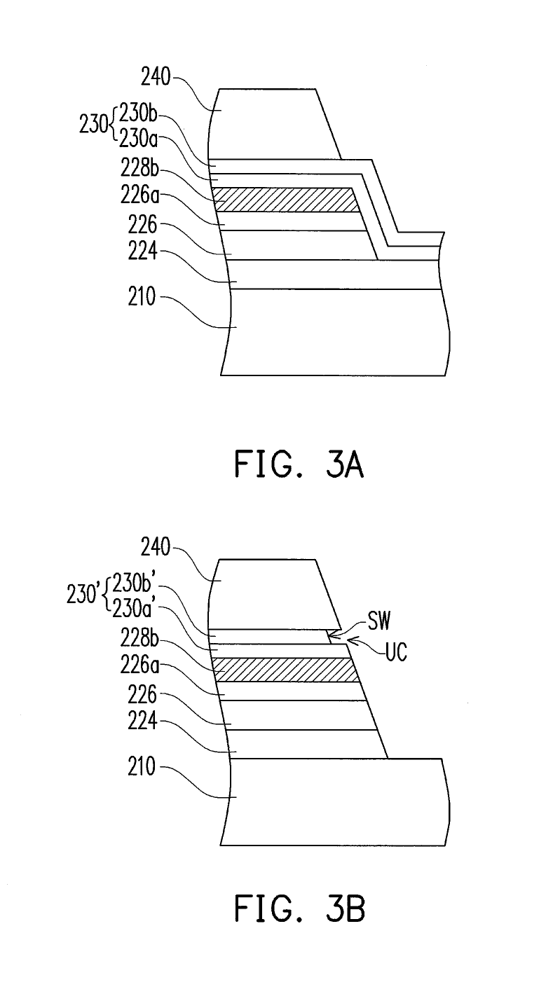

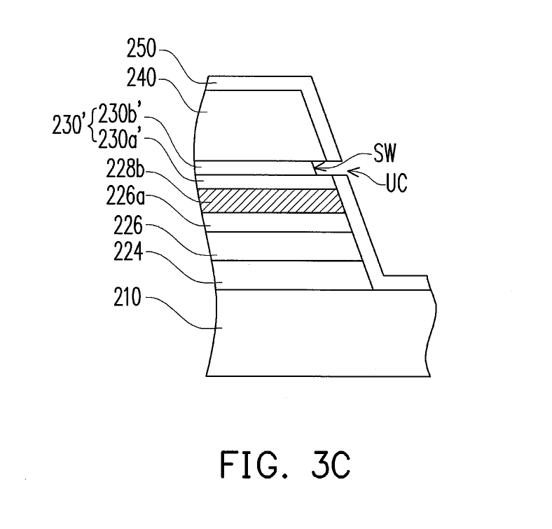

FIG. 3A to FIG. 3C are partial enlarged views of the structure within the smaller circle shown in FIG. 2B to FIG. 2D respectively. Referring to FIG. 2C and FIG. 3B, since etching rate R1 of the first thin film 230a is different from etching rate R2 of the second thin film 230b, the first thin film 230a and the second thin film 230b are etched to different degrees when the protection layer 230 is etched to form the patterned protection layer 230′. Accordingly, the patterned protection layer 230′ has an undercut UC at the sidewall SW of thereof. In this embodiment, the patterned protection layer 230′ includes a first patterned thin film 230a′ and a second patterned thin film 230b′, wherein the first patterned thin film 230a′ is disposed on the thin film transistor 220, the second patterned thin film 230b′ is disposed on the first patterned thin film 230a′, and etching rate R1 of the first patterned thin film 230a′ is smaller than etching rate R2 of the second patterned thin film 230b′.

In this embodiment, a portion of the drain 228b of the thin film transistor 220 and a portion of the second capacitor electrode 228c of the storage capacitor 220a are exposed by the patterned protection layer 230′ such that the drain 228b is capable of electrically connecting to a electrode material layer 250 (shown in FIG. 2D).

Referring to FIG. 2D and FIG. 3C, the electrode material layer 250 is formed to cover the substrate 210, the thin film transistor 220, the storage capacitor 220a, and the patterned photoresist layer 240. For example, the material of the electrode material layer 250 may consist of indium tin oxide, indium zinc oxide, indium tin zinc oxide, hafnium oxide, zinc oxide, aluminum oxide, aluminum tin oxide, aluminum zinc oxide, cadmium tin oxide, cadmium zinc oxide, any other appropriate material, or a combination thereof. As shown in FIG. 3C, the electrode material layer 250 is disconnected at the undercut UC naturally and exposes the undercut UC.

Referring to FIG. 2E, a pixel electrode 250a electrically connected to the thin film transistor 220 is formed by lifting off the patterned photoresist layer 240 and parts of the electrode material layer 250 covering the patterned photoresist layer 240 simultaneously through a stripper (not shown), wherein the stripper permeates from the undercut UC to an interface of the patterned photoresist layer 240 and the patterned protection layer 230′. In this embodiment, the pixel electrode 250a is electrically connected to the drain 228b and the second capacitor electrode 228c directly.

In this embodiment, the storage capacitor 220a includes the first capacitor electrode 222a, the gate insulating layer 224, and the second capacitor electrode 228c. In other words, the storage capacitor 220a is a Metal-Insulator-Metal (MIM) type capacitor.

FIG. 2F to FIG. 2J are cross-sectional views illustrating another fabricating method of a pixel unit according to the first embodiment of the present invention. Referring to FIG. 2F to FIG. 2J, the fabricating method of this embodiment is similar with the fabricating method illustrated in FIG. 2A to FIG. 2E except that the storage capacitor 220a′ of this embodiment is a Metal-Insulator-ITO (MII) type capacitor. In addition, the fabricating method of the storage capacitor 220a′ is different from that of the storage capacitor 220a illustrated in FIG. 2A to FIG. 2E. Since the fabrication method illustrated in FIG. 2G to FIG. 21 is similar with that illustrated in FIG. 2B to FIG. 2D, the detail description is omitted accordingly. Only a fabricating method of forming the storage capacitor 220a′ is described.

In this embodiment, no capacitor electrode is formed above the first capacitor electrode 222a when forming the source 228a and the drain 228b, as shown in FIG. 2F. In addition, the pixel electrode 250a is formed without extending above the first capacitor electrode 222a. However, a storage capacitor 220a′ is formed by coupling of the pixel electrode 250a and the first capacitor electrode 222a, as shown in FIG. 2J.

### The Second Embodiment

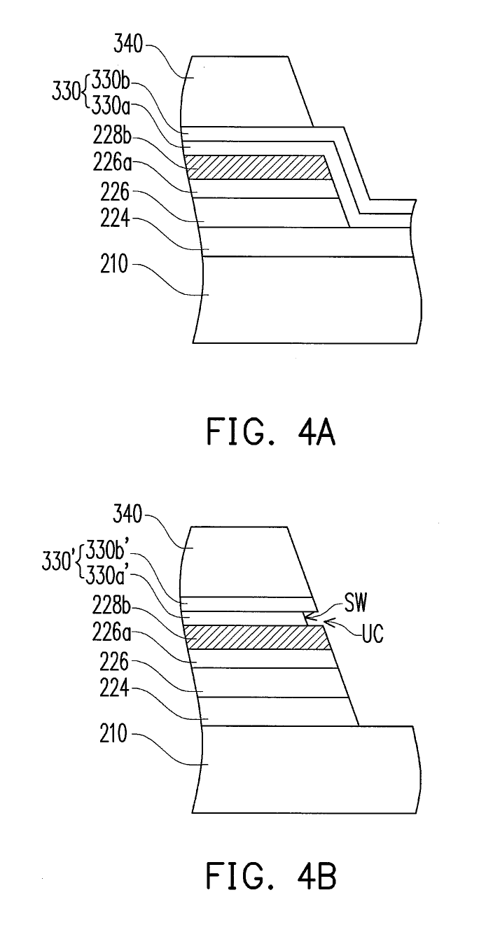

FIG. 4A and FIG. 4B are schematic cross-sectional views illustrating an undercut according to the second embodiment of the present invention. Referring to FIG. 4A and FIG. 4B, the protection layer 330 of this embodiment is similar with the protection layer 230 of the first embodiment except that etching rate R1 of the first thin film 330a is greater than etching rate R2 of the second thin film 330b. In addition, the first thin film 330a is a porous thin film and the second thin film 330b is a non-porous thin film, for example. In this embodiment, density of the above-mentioned porous thin film is between 0.01 g/cm³ to 1.49 g/cm³. In this embodiment, when a mixture of sulfur hexafluoride (SF₆), oxygen and nitrogen are used as gaseous etchant, etching rate R1 of the first thin film 330a is between 301 angstroms per second to 600 angstroms per second, and etching rate R2 of the second thin film 330b is between 1 angstrom per second to 300 angstroms per second.

As shown in FIG. 4B, the patterned protection layer 330′ has an undercut resulted from lateral etching, since etching rate R1 of the first thin film 330a is higher than etching rate R2 of the second thin film 330b.

### The Third Embodiment

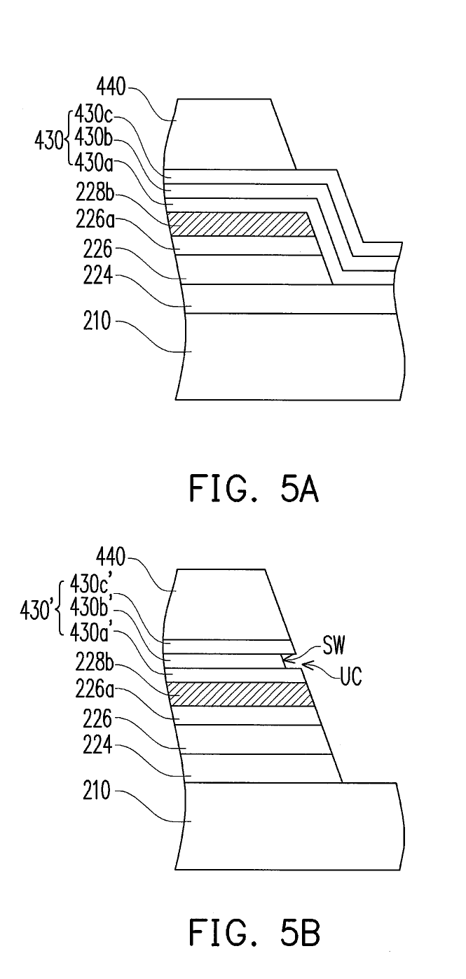

FIG. 5A and FIG. 5B are schematic cross-sectional views illustrating an undercut according to the third embodiment of the present invention. Referring to FIG. 5A and FIG. 5B, the protection layer 430 of this embodiment is similar with the protection layer 230 of the first embodiment except that the fabricating method of protection layer 430 further includes forming a third thin film 430c on the second thin film 430b entirely. In other words, the protection layer 430 includes a first thin film 430a, a second thin film 430b disposed on the first thin film 430a, and a third thin film 430c disposed on the second thin film 430b.

It is noted that etching rate R3 of the third thin film 430c is not limited in the present invention. For instance, etching rate R3 of the third thin film 430c is substantially the same with etching rate R1 of the first thin film 430a. More specifically, etching rate R1 of the first thin film 430a, etching rate R2 of the second thin film 430b and etching rate R3 of the third thin film 430c satisfy the formula: R2>R1=R3.

As shown in FIG. 5B, the patterned protection layer 430′ has an undercut UC resulted from lateral etching, since etching rate R2 of the second patterned thin film 430W is higher than etching rate R1 of the first patterned thin film 430a′ and etching rate R3 of the third patterned thin film 430c′.

### The Fourth Embodiment

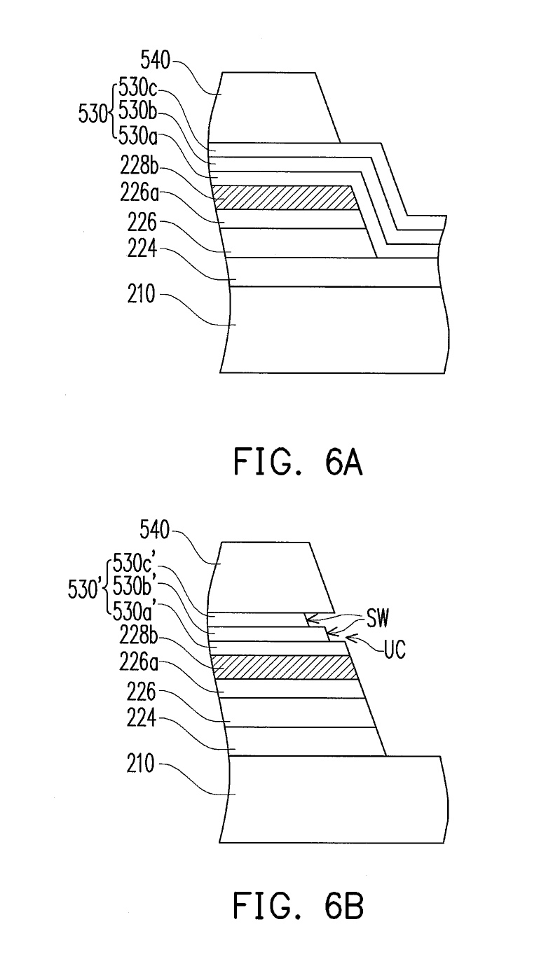

FIG. 6A and FIG. 6B are schematic cross-sectional views illustrating an undercut according to the fourth embodiment of the present invention. Referring to FIG. 6A and FIG. 6B, the protection layer 530 of this embodiment is similar with the protection layer 430 of the third embodiment except that etching rate R1 of the first thin film 530a, etching rate R2 of the second thin film 530b and etching rate R3 of the third thin film 530c satisfy the formula: R3>R2>R1.

As shown in FIG. 5B, the patterned protection layer 530′ has an undercut UC resulted from lateral etching, since etching rate R2 of the second patterned thin film 530b′ and etching rate R3 of the third patterned thin film 530c′ is higher than etching rate R1 of the first patterned thin film 530a′.

### The Fifth Embodiment

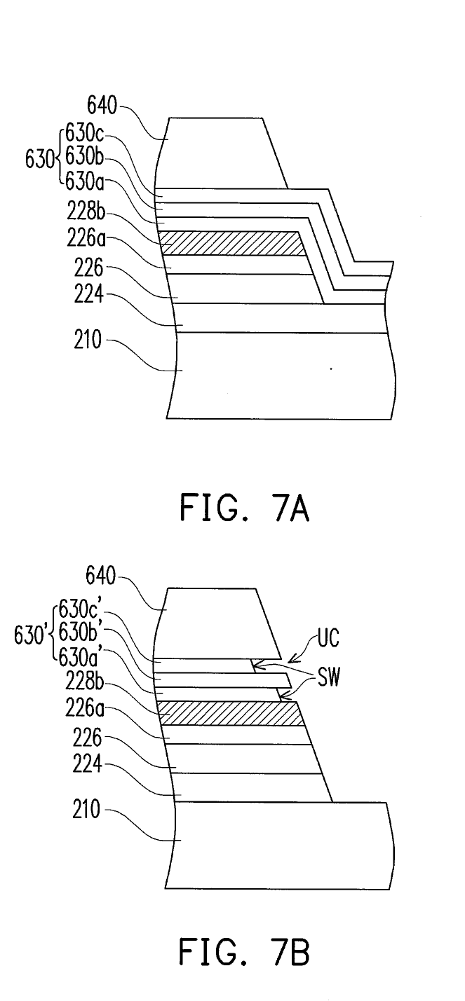

FIG. 7A and FIG. 7B are schematic cross-sectional views illustrating an undercut according to the fifth embodiment of the present invention. Referring to FIG. 7A and FIG. 7B, the protection layer 630 of this embodiment is similar with the protection layer 430 of the third embodiment except that etching rate R1 of the first thin film 630a, etching rate R2 of the second thin film 630b and etching rate R3 of the third thin film 630c satisfy the formula: R3=R1>R2.

As shown in FIG. 7B, the patterned protection layer 630′ has an undercut UC resulted from lateral etching, since etching rate R1 of the first patterned thin film 630a′ and etching rate R3 of the third patterned thin film 630c′ is higher than etching rate R2 of the second patterned thin film 630b′.

### The Sixth Embodiment

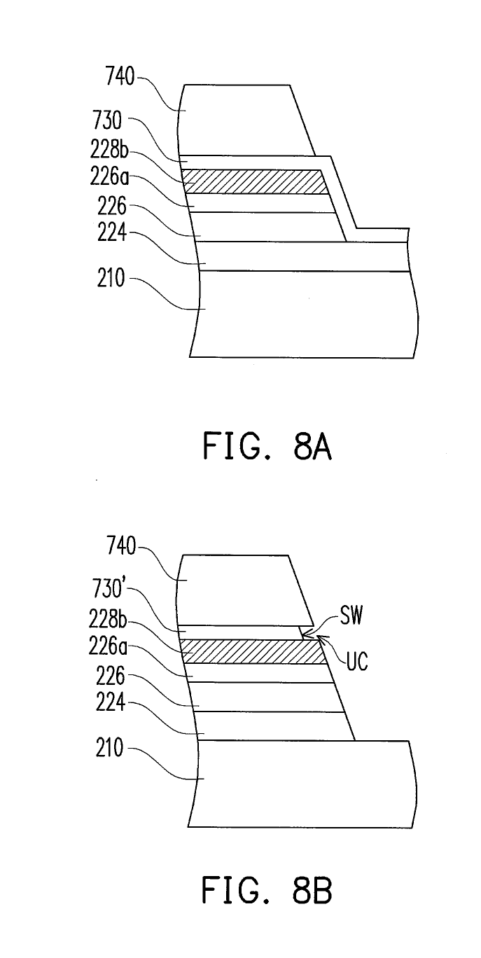

FIG. 8A and FIG. 8B are schematic cross-sectional views illustrating an undercut according to the sixth embodiment of the present invention. Referring to FIG. 8A and FIG. 8B, the protection layer 730 of this embodiment is similar with the protection layer 230 of the first embodiment except that the protection layer 730 is comprised of single thin film and the protection layer 730 is a porous thin film. In this embodiment, density of the above-mentioned porous thin film (i.e. the porous protection layer 730) is between 0.01 g/cm³ to 1.49 g/cm³. In this embodiment, when a mixture of sulfur hexafluoride (SF₆), oxygen and nitrogen are used as gaseous etchant, etching rate of the porous protection layer 730 is between 301 angstroms per second to 600 angstroms per second, for example.

A patterned porous protection layer 730′ is then formed by using the patterned photoresist layer 740 as a mask and partially removing the porous protection layer 740 uncovered by the patterned photoresist layer 740. Accordingly, the patterned porous protection layer 730′ has an undercut UC at the sidewall SW of thereof. Afterward, a pixel electrode (not shown) electrically connected to the thin film transistor 220 is formed by lifting off the patterned photoresist layer 740 and parts of the electrode material layer (not shown) covering the patterned photoresist layer 740 simultaneously through a stripper, wherein the stripper permeates from the undercut UC to an interface of the patterned photoresist layer 740 and the patterned porous protection layer 730′.

By adjusting materials and/or number of thin films of the protection layer, an undercut is formed at the sidewall of the patterned protection layer. The stripper permeates from the undercut such that the patterned photoresist layer and parts of the electrode material layer covering the patterned photoresist layer can be lifted off easily.

Although the present invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A fabricating method of a pixel unit, comprising:
forming a thin film transistor on a substrate;
forming a protection layer on the substrate entirely to cover the thin film transistor, wherein the protection layer comprises a plurality of thin films, the thin films are stacked, and an etching rate of at least one of the thin films is higher than an etching rate of the other thin films;
forming a patterned photoresist layer on the protection layer;
forming a patterned protection layer by using the patterned photoresist layer as a mask and partially removing the protection layer uncovered by the photoresist, wherein the patterned protection layer has an undercut located at a sidewall thereof;
forming a pixel electrode material layer to cover the substrate, the thin film transistor and the patterned photoresist layer, wherein the electrode material layer is disconnected at the undercut and exposes the undercut; and
forming a pixel electrode electrically connected to the thin film transistor by lifting off the patterned photoresist layer and parts of the pixel electrode material layer covering the patterned photoresist layer simultaneously through a stripper, wherein the stripper permeates from the undercut to an interface of the patterned photoresist layer and the patterned protection layer.

2. The fabricating method of claim 1, further comprising forming a storage capacitor on the substrate before entirely forming a protection layer on the substrate.

3. The fabricating method of claim 1, wherein the method of forming the thin film transistor comprises:
forming a gate on the substrate;
forming a gate insulating layer on the substrate to cover the gate;
forming a semiconductor layer on the gate insulating layer, wherein the semiconductor layer is located above the gate; and
forming a source and a drain on the semiconductor layer, wherein a portion of the drain is exposed by the patterned protection layer.

4. The fabricating method of claim 3, further comprising forming a storage capacitor on the substrate when forming the thin film transistor, a method of forming the storage capacitor comprises:
forming a first capacitor electrode on the substrate, wherein the first capacitor electrode is covered by the gate insulating layer; and
forming a second electrode on the gate insulating layer, wherein a portion of the second capacitor electrode is exposed by the patterned protection layer.

5. The fabricating method of claim 4, wherein the first capacitor electrode and the gate are formed simultaneously, and the second capacitor electrode, the source, and the drain are formed simultaneously.

6. The fabricating method of claim 4, wherein the pixel electrode is electrically connected to the drain and the second capacitor electrode directly.

7. The fabricating method of claim 3, further comprising forming a storage capacitor on the substrate when forming the thin film transistor, a method of forming the storage capacitor comprises:
forming a first capacitor electrode on the substrate, wherein the first capacitor electrode is covered by the gate insulating layer and the storage capacitor is formed by the first capacitor electrode, the gate insulating layer, and the pixel electrode.

8. The fabricating method of claim 7, wherein the first capacitor electrode and the gate are formed simultaneously, and the second capacitor electrode, the source, and the drain are formed simultaneously.

9. The fabricating method of claim 1, wherein a method of forming the protection layer comprises:
forming a first thin film on the substrate entirely to cover the thin film transistor; and
forming a second thin film on the first thin film entirely, wherein etching rate of the first thin film and etching rate of the second thin film are different.

10. The fabricating method of claim 9, wherein etching rate of the first thin film is greater than that of the second thin film.

11. The fabricating method of claim 10, wherein the first thin film is a porous thin film, and the second thin film is a non-porous thin film.

12. The fabricating method of claim 11, when a mixture of sulfur hexafluoride (SF₆), oxygen and nitrogen are used as a gaseous etchant, etching rate of the porous thin film is between 301 angstroms per second to 600 angstroms per second, and etching rate of the non-porous thin film is between 1 angstrom per second to 300 angstroms per second.

13. The fabricating method of claim 9, wherein etching rate of the first thin film is smaller than that of the second thin film.

14. The fabricating method of claim 12, wherein the first thin film is a non-porous thin film, and the second thin film is a porous thin film.

15. The fabricating method of claim 11, when a mixture of sulfur hexafluoride (SF₆), oxygen and nitrogen are used as a gaseous etchant, etching rate of the porous thin film is between 301 angstroms per second to 600 angstroms per second, and etching rate of the non-porous thin film is between 1 angstrom per second to 300 angstroms per second.

16. The fabricating method of claim 9, wherein a method of forming the protection layer further comprises:
forming a third thin film on the second thin film entirely.

17. The fabricating method of claim 16, wherein etching rate of the first thin film is smaller than that of the second thin film, and etching rate of the second thin film is smaller than that of the third thin film.

18. The fabricating method of claim 16, wherein etching rate of the first thin film is greater than that of the second thin film, and etching rate of the third thin film is smaller than that of the first thin film.

19. A fabricating method of a pixel unit, comprising:
forming a thin film transistor on a substrate;
forming a porous protection layer on the substrate entirely to cover the thin film transistor;
forming a patterned photoresist layer on the porous protection layer;
forming a patterned porous protection layer by using the patterned photoresist layer as a mask and partially removing the porous protection layer uncovered by the photoresist, wherein the patterned porous protection layer has an undercut located at a sidewall thereof;
forming a pixel electrode material layer to cover the substrate, the thin film transistor and the patterned photoresist layer, wherein the electrode material layer is disconnected at the undercut and exposes the undercut, and
forming a pixel electrode electrically connected to the thin film transistor by lifting off the patterned photoresist layer and parts of the pixel electrode material layer covering the patterned photoresist layer simultaneously through a stripper, wherein the stripper permeates from the undercut to an interface of the patterned photoresist layer and the patterned porous protection layer.

20. The fabricating method of claim 19, wherein density of the patterned porous protection layer is between 0.01 g/cm³ to 1.49 g/cm³.

21. The fabricating method of claim 19, wherein the method of forming the thin film transistor comprises:
forming a gate on the substrate;
forming a gate insulating layer on the substrate to cover the gate;
forming a semiconductor layer on the gate insulating layer, wherein the semiconductor layer is located above the gate; and
forming a source and a drain on the semiconductor layer, wherein a portion of the drain is exposed by the patterned protection layer.

22. The fabricating method of claim 21, further comprising forming a storage capacitor on the substrate when forming the thin film transistor, a method of forming the storage capacitor comprises:
forming a first capacitor electrode on the substrate, wherein the first capacitor electrode is covered by the gate insulating layer; and
forming a second capacitor electrode on the gate insulating layer, wherein a portion of the second capacitor electrode is exposed by the patterned protection layer.

23. The fabricating method of claim 22, wherein the first capacitor electrode and the gate are formed simultaneously, and the second capacitor electrode, the source, and the drain are formed simultaneously.

24. The fabricating method of claim 22, wherein the pixel electrode is electrically connected to the drain and the second capacitor electrode directly.

25. The fabricating method of claim 21, further comprising forming a storage capacitor on the substrate when forming the thin film transistor, a method of forming the storage capacitor comprises:
forming a first capacitor electrode on the substrate, wherein the first capacitor electrode is covered by the gate insulating layer and the storage capacitor is formed by the first capacitor electrode, the gate insulating layer, and the pixel electrode.

26. The fabricating method of claim 25, wherein the first capacitor electrode and the gate are formed simultaneously, and the second electrode, the source, and the drain are formed simultaneously.
